(19) United States
(12) Patent Application Publication
(10) Pub. No.: US 2025/0055253 A1
(43) Pub. Date: Feb. 13, 2025

(54) Wavelength Multiplex Light Source

(71) Applicant: Nippon Telegraph and Telephone Corporation, Tokyo (JP)

(72) Inventors: Erina Kanno, Musashino-shi, Tokyo (JP); Koji Takeda, Musashino-shi, Tokyo (JP); Shinji Matsuo, Musashino-shi, Tokyo (JP)

(21) Appl. No.: 18/717,970

(22) PCT Filed: Dec. 10, 2021
(86) PCT No.: PCT/JP2021/045564

§ 371 Date: Jun. 7, 2024

(51) Int. Cl. H01S 5/026; H01S 5/12; H01S 5/40

(52) U.S. Cl. CPC H01S 5/026; H01S 5/4012; H01S 5/4025; H01S 5/12

(57) ABSTRACT

A wavelength multiplexing light source includes: a plurality of semiconductor lasers; and a single waveguide in proximity to the semiconductor lasers via a low refractive index material, in which each of the plurality of semiconductor lasers has a diffraction grating and oscillates at a different wavelength, evanescent light is generated at an interface between the semiconductor lasers and the low refractive index material, and the evanescent light is coupled to the waveguide. Accordingly, the present invention can provide a wavelength multiplexing light source that is compact and operates in a single mode.

### TECHNICAL FIELD

The present invention relates to a wavelength multiplexing light source using a coupled optical waveguide.

### BACKGROUND ART

In order to perform large-capacity information transmission by wavelength division multiplexing (WDM), various wavelength multiplexing light sources have been developed.

In a wavelength multiplexing light source, a laser array inputs light from light sources having different oscillation wavelengths into an optical multiplexer from different waveguides and multiplexes the light. Non Patent Literature 1 discloses a wavelength multiplexing light source using four distributed feedback (DFB) lasers and a multimode interference (MMI) waveguide.

In addition, an integrated element of the light sources and the arrayed waveguide diffraction grating multiplexes light from the light sources having different oscillation wavelengths by an arrayed-waveguide grating (AWG). The AWG is a representative example of an optical multiplexer/demultiplexer for WDM, and divides a wavelength by using a multi-beam interference effect. For example, a wavelength multiplexing light source can be realized by integrating a small AWG (for example, Non Patent Literature 2) and a plurality of (for example, four) single mode light sources (for example, Non Patent Literature 3).

In addition, Non Patent Literature 4 discloses a wavelength multiplexing light source in which a plurality of (for example, four) disc resonator lasers are coupled in parallel to a thin wire waveguide of a silicon-on-insulator (SOI).

### CITATION LIST

### Non Patent Literature

Non Patent Literature 1: Xin Chen et al., “Monolithically integrated distributed feedback laser array wavelength-selectable light sources for WDM-PON application,” Optics Communications, Vol. 334, pp. 1-7 (2015).
Non Patent Literature 2: K. Sasaki, F. Ohno, A. Motegi, and T. Baba, “Arrayed waveguide grating of 70×60 μm2 size based on Si photonic wire waveguides,” Electronics Letters, Vol. 41, No. 14, pp. 801-802 (2005).
Non Patent Literature 3: A. X. Fang et al., “Electrically pumped hybrid AlGaInAs-silicon evanescent laser,” Optics Express, Vol. 14, No. 20, pp. 9203-9210 (2006).
Non Patent Literature 4: Joris Van Campenhout et al., “A Compact SOI-Integrated Multiwavelength Laser Source Based on Cascaded InP Microdisks,” IEEE Photonics Technology Letters, Vol. 20, No. 16, pp. 1345 (2008).

### SUMMARY OF INVENTION

### Technical Problem

The size of the laser array described above is 1000×1870 μm² (1.9 mm²) in 4-wave multiplexing. A waveguide having a large radius of curvature is used for this light source, and a bending waveguide and a multiplexer occupy a large area.

In an integrated element of a light source and an arrayed waveguide diffraction grating, in a case where the light source and the arrayed waveguide diffraction grating are connected by a Si thin wire waveguide, the size thereof is 340×1000 μm (0.3 mm²) in 4-wave multiplexing, and is smaller than that of a laser array. However, further miniaturization is required depending on applications.

In addition, although the wavelength multiplexing light source disclosed in Non Patent Literature 4 can be downsized, it is difficult to apply the wavelength multiplexing light source to wavelength multiplexing communication because the wavelength multiplexing light source performs multimode oscillation. For example, in Non Patent Literature 4, about 16.8 dB is reported as a side mode suppression ratio (SMSR), and it is difficult to apply it to wavelength multiplex communication.

As described above, in order to be applied to wavelength multiplexing communication, a wavelength multiplexing light source that is compact and operates in a single mode is required.

### Solution to Problem

In order to solve the problem as described above, a wavelength multiplexing light source according to the present invention includes: a plurality of semiconductor lasers; and a single waveguide in proximity to the semiconductor lasers via a low refractive index material, in which each of the plurality of semiconductor lasers has a diffraction grating and oscillates at a different wavelength, evanescent light is generated at an interface between the semiconductor lasers and the low refractive index material, and the evanescent light is coupled to the waveguide.

### Advantageous Effects of Invention

According to the present invention, a wavelength multiplexing light source that is compact and operates in a single mode can be provided.

### BRIEF DESCRIPTION OF DRAWINGS

FIG. 1 is a schematic diagram illustrating a configuration of a wavelength multiplexing light source according to a first embodiment of the present invention.

FIG. 2 is a diagram for explaining an operation of the wavelength multiplexing light source according to the first embodiment of the present invention.

FIG. 3 is a diagram for explaining an operation of the wavelength multiplexing light source according to the first embodiment of the present invention.

FIG. 4 is a diagram for explaining an operation of the wavelength multiplexing light source according to the first embodiment of the present invention.

FIG. 5A is a top perspective view of a configuration of the wavelength multiplexing light source according to a first example of the present invention.

FIG. 5B is a cross-sectional view taken along line VB-VB′ illustrating the configuration of the wavelength multiplexing light source according to the first example of the present invention.

FIG. 5C is a cross-sectional view taken along line VC-VC′ illustrating the configuration of the wavelength multiplexing light source according to the first example of the present invention.

FIG. 6 is a diagram for explaining a manufacturing method of the wavelength multiplexing light source according to the first example of the present invention.

FIG. 7A is a top perspective view of the configuration of the wavelength multiplexing light source according to the first example of the present invention.

FIG. 7B is a cross-sectional view taken along line VB-VB′ illustrating the configuration of the wavelength multiplexing light source according to the first example of the present invention.

FIG. 7C is a cross-sectional view taken along line VC-VC′ illustrating the configuration of the wavelength multiplexing light source according to the first example of the present invention.

FIG. 8 is a top perspective view illustrating a configuration of a wavelength multiplexing light source according to a second embodiment of the present invention.

FIG. 9A is a top perspective view illustrating a configuration of a wavelength multiplexing light source according to a third embodiment of the present invention.

FIG. 9B is a cross-sectional view taken along line VB-VB′ illustrating the configuration of the wavelength multiplexing light source according to the third embodiment of the present invention.

FIG. 9C is a cross-sectional view taken along line VC-VC′ illustrating the configuration of the wavelength multiplexing light source according to the third embodiment of the present invention.

FIG. 10 is a diagram for explaining a manufacturing method of the wavelength multiplexing light source according to the third embodiment of the present invention.

### DESCRIPTION OF EMBODIMENTS

### First Embodiment

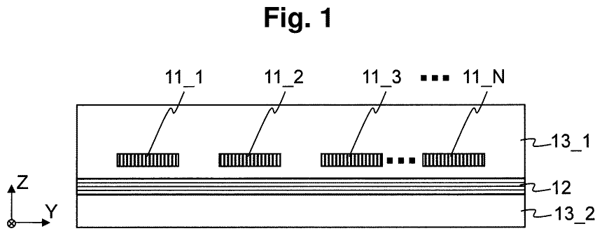

A wavelength multiplexing light source according to a first embodiment of the present invention will be described with reference to FIGS. 1 to 4.

### <Configuration of Wavelength Multiplexing Light Source>

As illustrated in FIG. 1, the wavelength multiplexing light source according to the present embodiment includes a plurality of semiconductor lasers 11_1 to 11_N, a semiconductor bus waveguide 12, and a low refractive index material 13_1. The plurality of semiconductor lasers 11_1 to 11_N are in proximity to the single waveguide 12 via the low refractive index material 13_1. The plurality of semiconductor lasers 11_1 to 11_N have diffraction gratings of different periods, oscillate at different wavelengths, and are arranged in a waveguide direction (Y direction in the drawing).

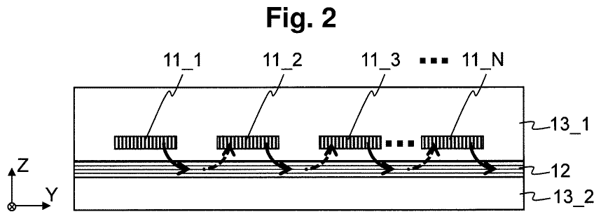

The laser light of the semiconductor lasers 11_1 to 11_N is evanescent coupled with the surrounding low refractive index material to emit evanescent light. Among the evanescent light, the evanescent light emitted toward the semiconductor bus waveguide 12 is coupled to the semiconductor bus waveguide 12 and propagates through the semiconductor bus waveguide 12 as illustrated in FIG. 2 (solid arrows in the drawing). Furthermore, light propagating through the semiconductor bus waveguide 12 may enter the semiconductor lasers 11_1 to 11_N (dotted arrows in the drawing).

Here, the semiconductor lasers 11_1 to 11_N and the semiconductor bus waveguide 12 are separated by a distance of about several microns or less, and the evanescent coupling strength can be changed by this distance and the structure of the semiconductor bus waveguide 12.

Since the plurality of semiconductor lasers 11_1 to 11_N oscillate laser light with different wavelengths, laser light of multiple wavelengths propagates through the semiconductor bus waveguide 12 and is emitted from an emission end face (not illustrated). Alternatively, it may be coupled to another optical element.

Next, coupling between light propagating through the semiconductor bus waveguide and the semiconductor laser was calculated. A coupled wave theory was used for the calculation. (J.-P. Weber, “Spectral characteristics of coupled-waveguide Bragg-reflection tunable optical filter,” IEEE Proceedings Journal, Vol. 140, No. 5, pp. 275-284 (1993). Wei Shi et al., “Silicon photonic grating-assisted, contra-directional couplers,” Optics Express, Vol. 21, No. 3, pp. 181375 (2013)).

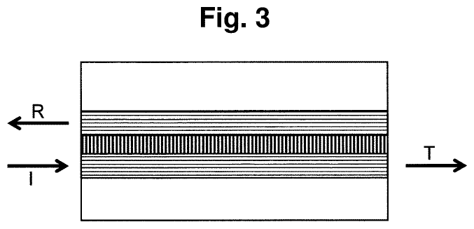

In addition, in the structure in which waveguides are coupled to the diffraction grating illustrated in FIG. 3, with respect to incident light I incident from one end of one waveguide, transmitted light T emitted from the other end of the one waveguide and reflected light R emitted from one end of the other waveguide were calculated. In addition, in the calculation, the refractive indexes of the materials were set to 2.61 and 2.45, and the coupling coefficient was set to 183 cm⁻¹.

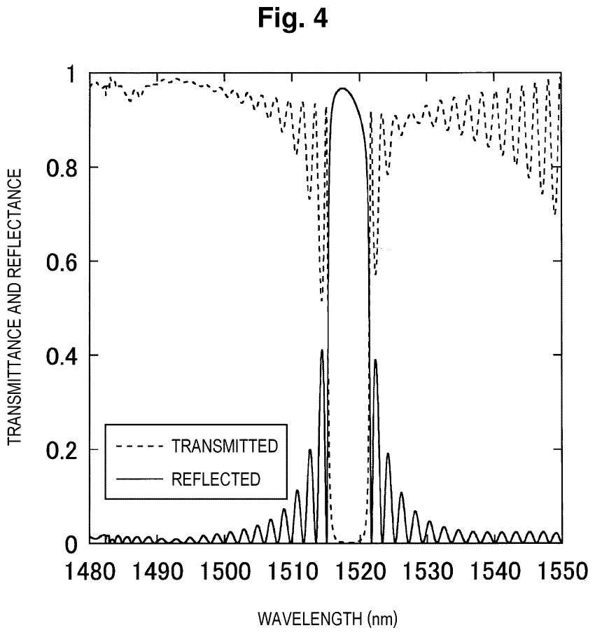

FIG. 4 illustrates a spectrum of reflected light (solid line in the drawing) and a spectrum of transmitted light (dotted line in the drawing) with respect to the incident light I.

As illustrated in FIG. 4, the reflected light spectrum has a resonance peak at a wavelength of about 1518 nm. On the other hand, the transmitted light spectrum also has a resonance peak at a wavelength of about 1518 nm. In the transmitted light spectrum, the transmittance is about 1.0 in a wavelength region of less than 1510 nm and longer than 1525 nm.

This indicates that when there is a predetermined wavelength difference between the wavelength of the incident light and the resonance wavelength of the diffraction grating of the semiconductor laser, the incident light is transmitted without being reflected by the diffraction grating. For example, in the structure used for the above calculation, the predetermined wavelength difference may be 15 nm or more.

Therefore, in the present embodiment, even if the laser light propagating to the semiconductor bus waveguide is incident on another semiconductor laser, the laser light is transmitted without being reflected by the diffraction grating of the other semiconductor laser, so that the laser light does not interfere with the laser light of the other semiconductor laser and does not affect the oscillation of the other semiconductor laser to be unstable, or the like.

In other words, by setting a predetermined wavelength difference between the wavelength of the incident light and the resonance wavelength of the diffraction grating of the semiconductor laser, that is, by setting the period of the diffraction grating of one semiconductor laser among the plurality of semiconductor lasers to transmit the oscillation light of the other semiconductor laser, it is possible to avoid the oscillation light of the other semiconductor laser from affecting the operation of the one semiconductor laser.

### First Example

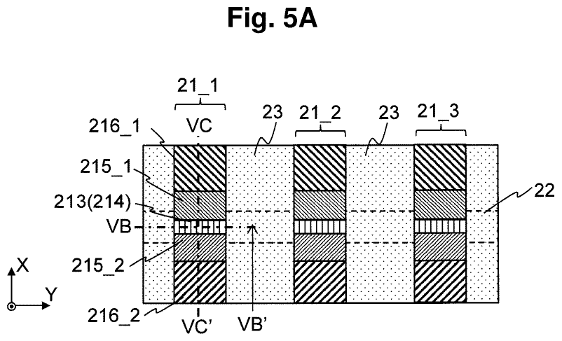

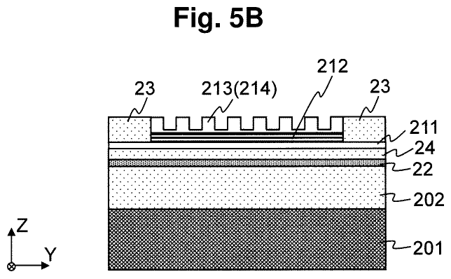

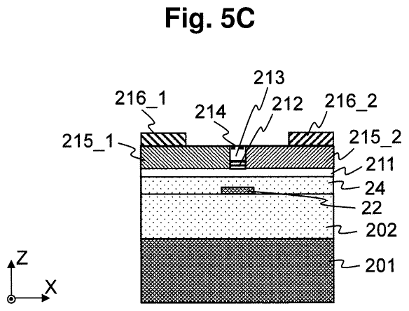

A wavelength multiplexing light source according to a first example of the present invention will be described with reference to FIGS. 5A to 7B.

### <Configuration of Wavelength Multiplexing Light Source>

As illustrated in FIGS. 5A to 5C, a wavelength multiplexing light source 20 according to the present example includes a plurality of (for example, three) DFB lasers 21_1 to 21_3 and a semiconductor bus waveguide 22.

As illustrated in FIG. 5A, in the wavelength multiplexing light source 20, the plurality of DFB lasers 21_1 to 21_3 are arranged in the waveguide direction (Y direction in the drawing), and insertion layers 23 are arranged in the respective gaps between the plurality of DFB lasers 21_1 to 21_3. Each of the insertion layers 23 is made of SiO₂, may be a dielectric such as SiN, or may be a material having a refractive index lower than the refractive index of the material (for example, an InP-based semiconductor) constituting the DFB lasers.

The length of the DFB lasers 21_1 to 21_3 is 100 μm, and the intervals between the DFB lasers 21_1 to 21_3 in the waveguide direction, that is, the length of the insertion layers 23 in the waveguide direction is 200 μm.

As illustrated in FIG. 5B, the wavelength multiplexing light source 20 includes an SiO₂ layer 202, the semiconductor bus waveguide 22, a coupling layer 24, and the DFB lasers 21_1 to 21_3 in this order on a Si substrate 201. In this manner, the semiconductor bus waveguide 22 is disposed in proximity to the DFB lasers 21_1 to 21_3.

The semiconductor bus waveguide 22 is made of Si, and may be a material capable of propagating the laser light of the DFB lasers 21_1 to 21_3. The width thereof is 3 μm and the thickness thereof is 100 nm.

The coupling layer 24 is made of SiO₂, may be a dielectric such as SiN, or may be a material having a refractive index lower than the refractive index of the material (for example, an InP-based semiconductor) constituting the DFB lasers. The thickness thereof, that is, the interval between the semiconductor bus waveguide 22 and the DFB lasers 21_1 to 21_3 is 250 nm. This interval may be 100 nm to 500 nm, and may be in a range in which evanescent light can be coupled to the semiconductor bus waveguide 22.

In the DFB lasers 21_1 to 21_3, a first semiconductor layer (InP) 211, a multi-quantum well (MQW) 212 as an active layer, and a second semiconductor layer (InP) 213 are layered as illustrated in FIGS. 5A and 5C. The width of the multilayered structure, that is, the width of the active layer is about 1.0 μm. A p-type semiconductor (InP) layer 215_1 is disposed in contact with one side surface of the active layer 212 in the width direction (X direction in the drawing), and a p-type electrode (for example, gold) 216_1 is provided thereon via a p-type contact layer (for example, p-type InGaAs, not illustrated). In addition, an n-type semiconductor (InP) layer 215_2 is disposed in contact with the other side surface of the active layer 212, and an n-type electrode (for example, gold) 2162 is provided thereon via an n-type contact layer (for example, n-type InGaAs, not illustrated).

Here, for example, the MQW active layer 212 includes an InGaAsP well layer and an InGaAsP barrier layer in a 1.55 μm wavelength band, and has a thickness of about 105 nm with six cycles. The thicknesses of the first semiconductor layer (InP) 211 and the second semiconductor layer (InP) 213 are 165 nm and 80 nm, respectively. The p-type semiconductor (InP) layer 215_1 and the n-type semiconductor (InP) layer 215_2 have a thickness of 350 nm.

Here, the MQW active layer 212 may have a wavelength band of 1.31 μm. For MQW, InGaAs, GaInNAs, or the like may be used in addition to InGaAsP. The configuration such as the period and the thickness of the MQW may be another configuration.

In the DFB lasers 21_1 to 21_3, the DFB diffraction grating 214 is provided on the upper surface of the second semiconductor layer (InP) 213 above the active layer 212. The coupling coefficient of the DFB diffraction grating 214 is determined by the refractive index of InP and the refractive index of air. Here, in the DFB diffraction grating 214, for example, a pitch (period) is about 200 nm to 300 nm, a depth is about 10 nm to 50 nm, and is set by a desired emission (oscillation) wavelength or coupling coefficient.

In addition, a diffraction grating may be provided at a boundary between the active layer 212 and the first semiconductor layer (InP) below the active layer.

As described above, the DFB lasers 21_1 to 21_3 have a membrane-type laser configuration, and a current is injected into the active layer 212 in the lateral direction (width direction), laser oscillation is performed, and laser light is emitted (arrow 15 in the drawing).

The plurality of DFB lasers 21_1 to 21_3 oscillate laser light at different wavelengths, for example, 1505 nm, 1520 nm, and 1535 nm.

The laser light of the DFB lasers 21_1 to 21_3 is evanescent coupled to the coupling layer to emit evanescent light. This evanescent light is coupled to the semiconductor bus waveguide 22 and propagates through the semiconductor bus waveguide 22.

Since the plurality of DFB lasers 21_1 to 21_3 oscillate laser light with different wavelengths, laser light of multiple wavelengths propagates through the semiconductor bus waveguide 22 and is emitted from an emission end face (not illustrated). Alternatively, it may be coupled to another optical element.

### <Manufacturing Method of Wavelength Multiplexing Light Source>

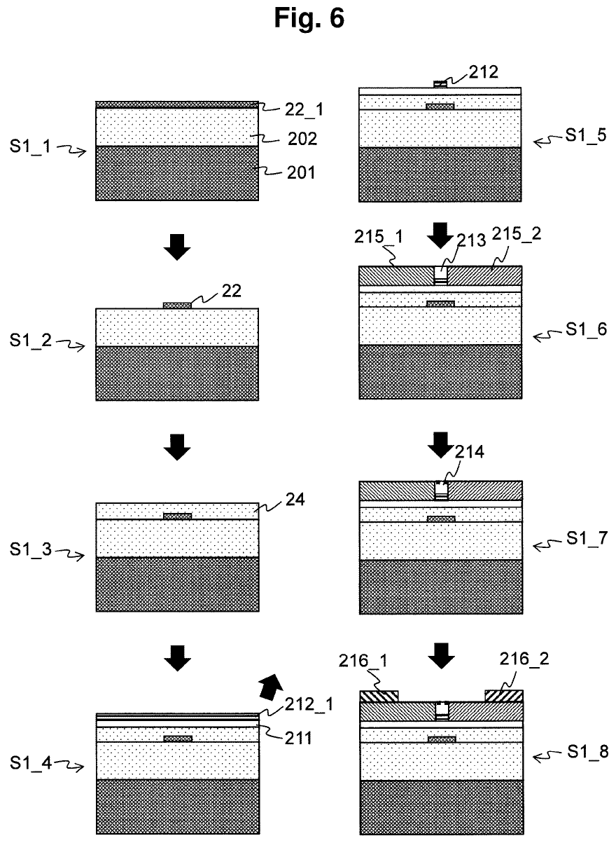

A manufacturing method of the wavelength multiplexing light source 20 according to the present example will be described with reference to FIG. 6. FIG. 6 is a cross-sectional view taken along line VC-VC′ of the wavelength multiplexing light source 20.

First, an SOI substrate including the Si substrate 201, the SiO₂ layer 202, and the Si layer 221 is used (S1_1), and the Si layer 22_1 of the SOI substrate is processed by lithography, dry etching, or the like to form the semiconductor bus waveguide 22 (S1_2).

Next, a film of SiO₂ 24 is formed by a method such as chemical vapor deposition (CVD), and a surface thereof is planarized by a method such as chemical mechanical polishing (CMP) (S1_3).

Next, a wafer including the active layer crystal 212_1 is bonded by a method such as wafer bonding, and a support substrate is removed to form the semiconductor thin films 211, 212_1 containing the active layer crystal on the SiO₂ 24 of the SOI substrate processed in step (S1_3) (S1_4).

Next, the semiconductor thin films 211, 212_1 containing the active layer crystal are processed by etching to form the active layer (waveguide structure) 212 (S1_5). As a result, the laser structure and the semiconductor bus waveguide 22 can be arranged in parallel in the vertical direction (Z direction in the drawing).

Next, the active layer is filled with InP by crystal regrowth. Next, p-type InP 215_1 is formed on one side surface, and n-type InP 215_2 is formed on the other side surface (S1_6). For example, the p-type InP 215_1 is formed by Zn diffusion, and the n-type InP layer 215_2 is formed by ion implantation. As a result, the undoped InP layer 213 is formed on the active layer 212.

Next, the diffraction grating 214 is formed on a surface (upper surface) of the InP layer 213 on the active layer (S1_7).

Finally, electrodes 2161, 216_2 are formed on the p-type InP 215_1 and the n-type InP 215_2, respectively (S1_8).

In the wavelength multiplexing light source 20, since the optical coupling intensity between the DFB lasers 21_1 to 21_3 and the semiconductor bus waveguide 22 strongly depends on the interval between the DFB lasers 21_1 to 21_3 and the semiconductor bus waveguide 22, control of this interval is important. In the wavelength multiplexing light source 20, since the interval between the DFB lasers 21_1 to 21_3 and the semiconductor bus waveguide 22 corresponds to the thickness of the coupling layer 24, the control of this interval depends on the accuracy of film formation and the accuracy of CMP.

On the other hand, when the DFB lasers 21_1 to 21_3 and the semiconductor bus waveguide 22 are arranged in the horizontal direction, the manufacturing error of the interval between the DFB lasers 21_1 to 21_3 and the semiconductor bus waveguide 22 depends on the accuracy of lithography etching.

Therefore, since the accuracy of normal film formation is higher than the accuracy of lithography etching, the coupling of light between the DFB lasers and the semiconductor bus waveguide can be controlled with high accuracy according to the manufacturing method according to the present embodiment.

### <Effects>

When an integrated element (Non Patent Literature 2 and 3) of a light source and an arrayed waveguide diffraction grating is assumed as a conventional wavelength multiplexing light source, the size thereof is 340×1000 μm (0.3 mm²) as described above.

On the other hand, when it is assumed that a laser having the same size as the light source (laser) of the conventional wavelength multiplexing light source is used, the size of the wavelength multiplexing light source according to the present embodiment is 60×1150 μm (0.07 mm²), and can be reduced to about ⅕ as compared with the conventional wavelength multiplexing light source.

Furthermore, in the wavelength multiplexing light source according to the present embodiment, since the semiconductor laser resonates by the diffraction grating, the oscillation wavelength thereof can be easily controlled by changing the period of the diffraction grating, and favorable single-mode characteristics can be realized with SMSR of 40 dB or more.

As described above, the wavelength multiplexing light source according to the present embodiment can realize a wavelength multiplexing light source that is compact and operates in a single mode.

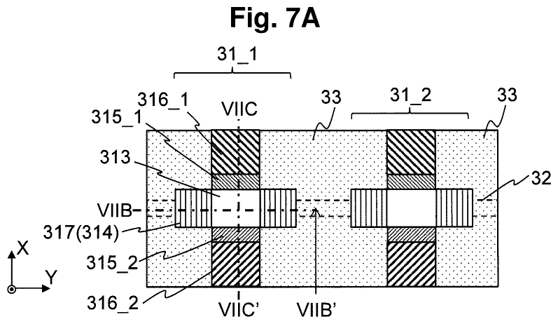

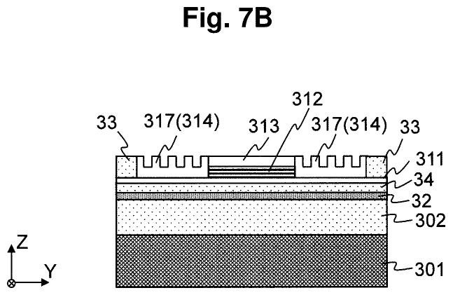

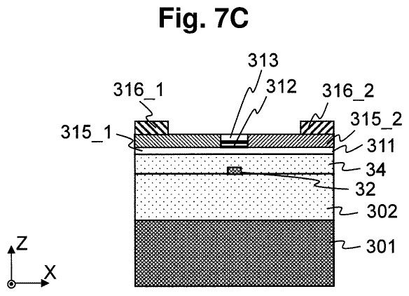

In the present embodiment, an example of using a DFB laser as a semiconductor laser has been described, but the present invention is not limited thereto, and a distributed Bragg reflector (DBR) laser may be used as illustrated in FIGS. 7A to 7C. When the DBR laser is used, spatial hole burning can be suppressed as compared with the DFB laser, and the stability of the mode can be improved.

### Second Embodiment

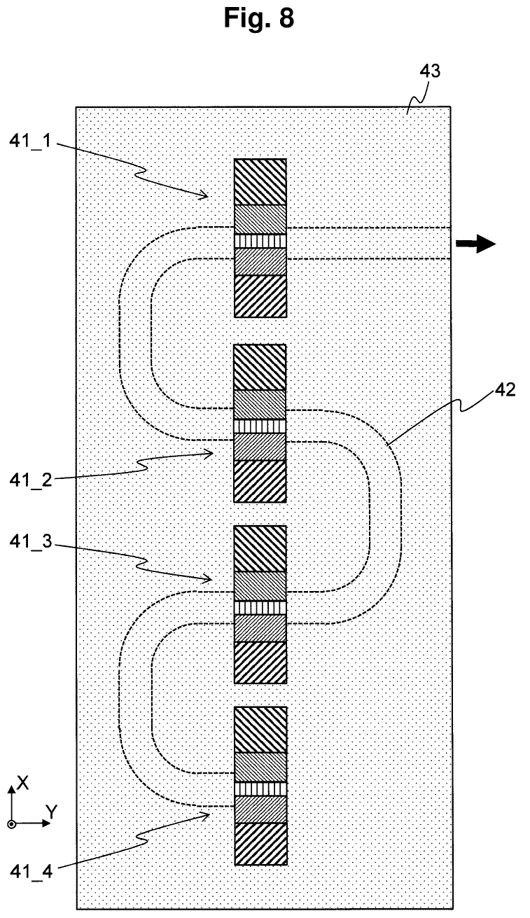

A wavelength multiplexing light source according to a second embodiment of the present invention will be described with reference to FIG. 8.

### <Configuration of Wavelength Multiplexing Light Source>

As illustrated in FIG. 8, a wavelength multiplexing light source 40 according to the present embodiment includes a plurality of semiconductor lasers 41_1 to 414, and a semiconductor bus waveguide 42. The plurality of semiconductor lasers 41_1 to 41_4 have different oscillation wavelengths and are arranged in the width direction (X direction in the drawing).

n addition, the semiconductor bus waveguide 42 is linearly arranged in the waveguide direction (Y direction in the drawing) in regions in proximity to the semiconductor lasers 41_1 to 414, but is arranged to be curved in regions between the semiconductor lasers 41_1 to 41_4. In this manner, the semiconductor bus waveguide 42 has an S-shape as a whole. The other configurations are the same as those of the first embodiment.

According to the wavelength multiplexing light source of the present embodiment, wiring can be shortened, so that excellent high frequency characteristics can be realized.

Furthermore, in the present embodiment, by using a Si fine wire waveguide having a small bending radius, this configuration can be realized without increasing the element size.

In addition, in the wavelength multiplexing light source according to the present embodiment, by adopting a configuration in which the diffraction grating is not provided in the semiconductor laser structure (for example, 41_4) on the opposite side of the emission end, it is possible to monitor the intensity of output light from the wavelength multiplexing light source by using the semiconductor laser structure as a simplified light receiver.

### Third Embodiment

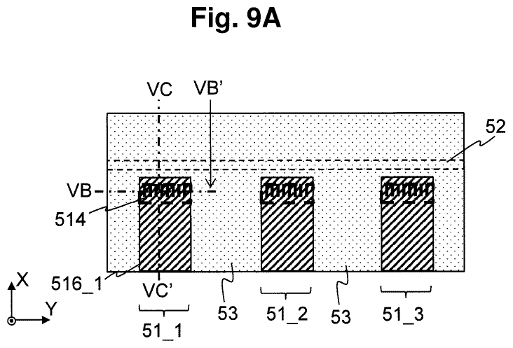

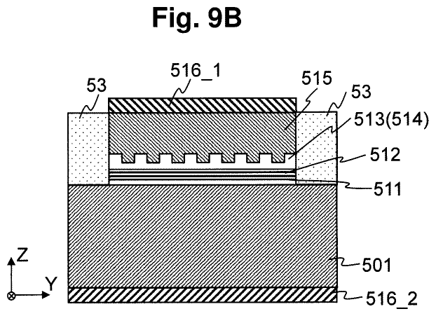

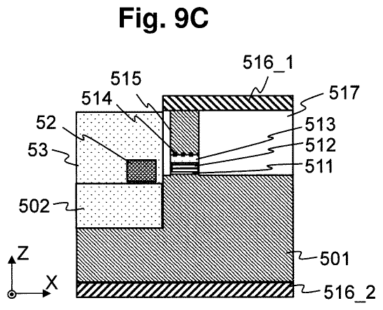

A wavelength multiplexing light source according to a third embodiment of the present invention will be described with reference to FIG. 9.

### <Configuration of Wavelength Multiplexing Light Source>

As illustrated in FIGS. 9A to 9C, a wavelength multiplexing light source according to the present example includes a plurality of DFB lasers 51_1 to 51_3 and a semiconductor bus waveguide 52.

As illustrated in FIG. 9A, in the wavelength multiplexing light source, the plurality of DFB lasers 51_1 to 51_3 are arranged in the waveguide direction (Y direction in the drawing), and insertion layers 53 are arranged in the respective gaps between the plurality of DFB lasers 51_1 to 51_3.

The DFB lasers 51_1 to 51_3 include an InP layer 511, an active layer 512 including MQW, an InP layer 513, and a p-type InP cladding 515_1 in this order on the n-type InP substrate 501. In addition, an n-type electrode 516_2 is provided on a back surface of the n-type InP substrate, and an n-type electrode 516_1 is provided on a surface of the p-type InP cladding.

The semiconductor bus waveguide 52 is disposed in proximity to side walls of the DFB lasers 51_1 to 51_3 in the width direction (X direction in the drawing). In addition, the semiconductor bus waveguide 52 is formed on the SiO₂ 502 provided on the n-type InP substrate 501, and a side wall and an upper surface thereof are covered with the SiO₂ cladding (insertion layer) 53.

Here, the side walls of the DFB lasers 51_1 to 51_3 and the side wall of the semiconductor bus waveguide 52 are in proximity to each other in the width direction via a semi-insulating InP buried layer 517 and the SiO₂ cladding (insertion layer) 53. The sum of the widths of the semi-insulating InP buried layer 517 and the SiO₂ cladding (insertion layer) 53, that is, the interval between the side walls of the DFB laser 51_1 to 51_3 and the side wall of the semiconductor bus waveguide 52 may be 100 nm to 500 nm.

In addition, the semiconductor bus waveguide 52 has a width of 3 μm and a thickness of 100 nm.

The other configurations are substantially similar to those of the first embodiment.

### <Manufacturing Method of Wavelength Multiplexing Light Source>

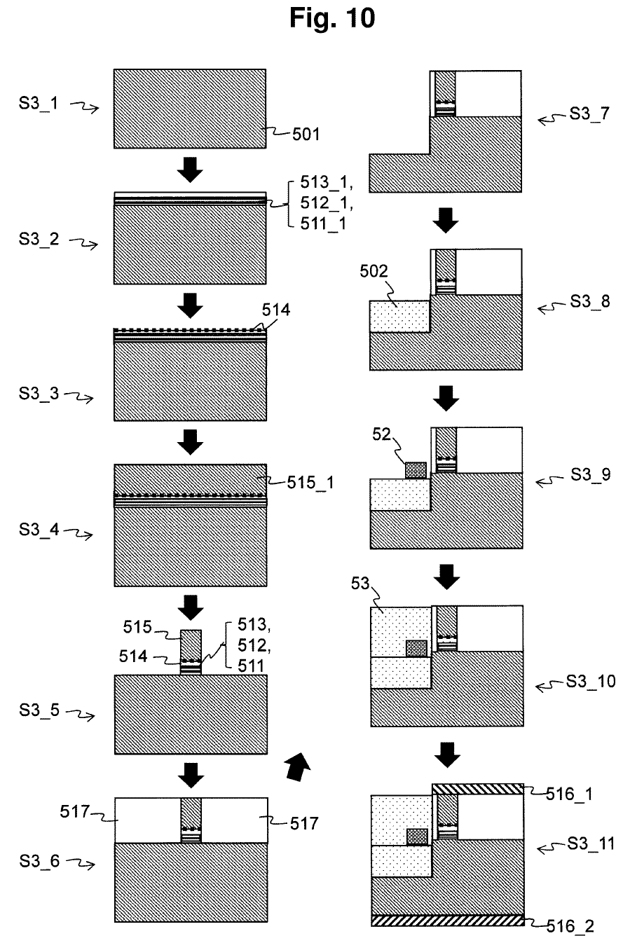

A manufacturing method of the wavelength multiplexing light source according to the present example will be described with reference to FIG. 10. FIG. 10 is a cross-sectional view taken along line VIVC-VIVC′ of the wavelength multiplexing light source.

First, using the n-type InP substrate 501 (S3_1), the InP layer 511_1, the active layer 512_1, and the InP layer 513_1 are sequentially crystal-grown on the n-type InP substrate 501 (S3_2).

Next, a diffraction grating 514 is formed in the upper optically confinement InP layer (S3_3).

Next, the p-type InP 515_1 is crystal-grown on the InP layer 513_1 on which the diffraction grating 514 is formed (S3_4).

Next, the crystal-grown multilayered structure is etched to form a mesa structure (S3_5).

Next, lateral regions of the mesa structure are filled with the semi-insulating (S.I.) InP 517 by crystal regrowth (S3_6).

Next, the semi-insulating InP layer 517 and a part of the n-type InP substrate 501 in one of the lateral regions of the mesa structure are removed by etching (S3_7). At this time, etching is performed such that the semi-insulating InP layer 517 remains with a thickness (width) of about 100 to 500 nm on one side wall of the mesa structure.

Next, a film of SiO₂ 502 is formed in the removed region in the n-type InP substrate 501 (S3_8).

Next, after a film of amorphous Si is formed on the formed SiO₂ 502, etching is performed to form the amorphous Si waveguide 52 (S3_9). Here, the material of the waveguide 52 is not limited to amorphous Si, and may be a high refractive index material.

Next, a film of SiO₂ 53 is formed so as to cover the amorphous Si waveguide 52 (S3_10).

Finally, the n-type electrode 516_2 is formed on the back surface of the n-type InP substrate 501, and the p-type electrode 516_1 is formed on the surface of the p-type InP 515. At this time, the n-type electrode 516_2 and the p-type electrode 516_1 may be formed on the back surface of the n-type InP substrate 501 and the front surface of the p-type InP 515, respectively, via an ohmic contact layer.

Reliability of the configuration of the embedded DFB laser used in the present embodiment has already been demonstrated. Therefore, the wavelength multiplexing light source according to the present embodiment can improve reliability.

In the embodiment of the present invention, an example of the configuration of the semiconductor laser in the 1.55 μm wavelength band has been described, but another wavelength band such as 1.31 μm may be used. In addition, an example of the configuration using an InP-based compound semiconductor as a layer configuration of a semiconductor laser such as an active layer, a waveguide layer, and p-type and n-type semiconductor layers has been described. However, other InP-based compound semiconductors may be used, other semiconductors such as GaAs-based and Si-based semiconductors may be used, and materials that can constitute a semiconductor laser may be used.

The embodiments of the present invention describe examples of the structures, dimensions, materials, and the like of the respective components in the configuration, manufacturing method, and the like regarding wavelength multiplexing light sources, but the present invention is not limited thereto. A wavelength multiplexing light source is only required to exhibit its functions and achieve its effects.

### INDUSTRIAL APPLICABILITY

The present invention relates to a wavelength multiplexing light source, and can be applied to a wavelength division multiplexing (WDM) communication system and the like.

### REFERENCE SIGNS LIST

10 WAVELENGTH MULTIPLEXING LIGHT SOURCE
11_1 to 11_N Semiconductor laser
12 Semiconductor bus waveguide
13_1, 13_2 Low refractive index material

1. A wavelength multiplexing light source comprising:
a plurality of semiconductor lasers; and
a single waveguide in proximity to the semiconductor lasers via a low refractive index material; wherein
each of the plurality of semiconductor lasers has a diffraction grating and oscillates at a different wavelength,
evanescent light is generated at an interface between the semiconductor lasers and the low refractive index material, and
the evanescent light is coupled to the waveguide.

2. The wavelength multiplexing light source according to claim 1, wherein
a period of the diffraction grating of one of the plurality of semiconductor lasers is set to transmit oscillation light of another semiconductor laser.

3. The wavelength multiplexing light source according to claim 1, wherein
an interval between the semiconductor lasers and the waveguide is 100 nm or more and 500 nm or less.

4. The wavelength multiplexing light source according to claim 1, comprising, in this order:
a substrate;
the waveguide;
the low refractive index material; and
the semiconductor lasers, wherein
each of the semiconductor lasers includes:
a waveguide structure including a first semiconductor layer, an active layer, and a second semiconductor layer in order from the low refractive index material; and
a p-type semiconductor layer disposed in contact with one side surface of the active layer; and
an n-type semiconductor layer disposed in contact with another side surface of the active layer, and
the diffraction grating is disposed on one of an upper surface of the second semiconductor layer or a lower surface of the first semiconductor layer.

5. The wavelength multiplexing light source according to claim 1, wherein
the plurality of semiconductor lasers are arranged in a waveguide direction.

6. The wavelength multiplexing light source according to claim 1, wherein
the plurality of semiconductor lasers are arranged in a horizontal direction.

7. The wavelength multiplexing light source according to claim 1, comprising:
a waveguide structure including, in this order, a substrate, a first semiconductor layer, an active layer, a second semiconductor layer, and a cladding layer;
a semi-insulating semiconductor layer disposed in contact with both side surfaces of the active layer; and
the waveguide disposed in proximity to one of the side surfaces of the active layer.

8. The wavelength multiplexing light source according to claim 1, wherein
the waveguide is Si.
